(19) United States
(12) Patent Application Publication
(10) Pub. No.: US 2025/0372514 A1
(43) Pub. Date: Dec. 4, 2025

(54) FEED-THROUGH VIA DEVICE, LAYOUT, AND METHOD

(71) Applicant: TAIWAN SEMICONDUCTOR MANUFACTURING COMPANY, LTD., Hsinchu (TW)

(72) Inventors: Sheng-Feng HUANG, Hsinchu (TW); Ching-Yu HUANG, Hsinchu (TW); Yuan Yu HUANG, Hsinchu (TW); Wei-Cheng LIN, Hsinchu (TW); Jiann-Tyng TZENG, Hsinchu (TW)

(21) Appl. No.: 18/912,207

(22) Filed: Oct. 10, 2024

Related U.S. Application Data
(60) Provisional application No. 63/655,253, filed on Jun. 3, 2024.

(51) Int. Cl. H01L 23/528; G06F 30/392; H01L 21/28; H01L 21/768; H01L 21/8234; H01L 29/423

(52) U.S. Cl. CPC H01L 23/5283; H01L 21/28; H01L 21/76877; H01L 23/5286; H10D 84/0149; H10D 84/038; G06F 30/392; H10D 64/411

(57) ABSTRACT

An IC device includes an active area extending in a first direction in a front side of a semiconductor substrate, a first gate electrode overlying the active area and extending in a second direction perpendicular to the first direction, a metal-like defined (MD) segment extending in the second direction adjacent to the first gate electrode and overlying the active area, and a first feed-through via (FTV) directly contacting one of the first gate electrode or the MD segment and extending in a third direction perpendicular to the first and second directions to a back side of the semiconductor substrate.

### PRIORITY CLAIM

The present application claims the priority of U.S. Provisional Application No. 63/655,253, filed Jun. 3, 2024, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are plan and cross-sectional views of an IC device and layout diagram, in accordance with some embodiments.

FIGS. 2A and 2B are plan and cross-sectional views of an IC device and layout diagram, in accordance with some embodiments.

FIGS. 3A and 3B are plan and cross-sectional views of an IC device and layout diagram, in accordance with some embodiments.

FIGS. 4A and 4B are plan views of an IC device and layout diagram, in accordance with some embodiments.

FIGS. 5A-5C are schematic and plan views of an IC device and layout diagram, in accordance with some embodiments.

FIG. 6A-6D are plan and schematic views of an IC device and layout diagram, in accordance with some embodiments.

FIG. 7 is a flowchart of a method of manufacturing an IC, in accordance with some embodiments.

FIG. 8 is a flowchart of a method of generating an IC layout diagram, in accordance with some embodiments.

FIG. 9 is a block diagram of an IC layout diagram generation system, in accordance with some embodiments.

FIG. 10 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device and corresponding layout diagram and manufacturing method include an active area extending in a front side of a semiconductor substrate, a gate electrode overlying and perpendicular to the active area, a metal-like defined (MD) segment overlying the active area adjacent to the gate electrode, and a feed-through via (FTV) directly contacting one of the gate electrode or the MD segment and extending to a back side of the semiconductor substrate.

Compared to other approaches, e.g., those in which FTVs directly contact frontside metal lines, the IC device is thereby capable of using fewer frontside metal lines for FTV-based signal and power supply connections, thereby enabling a smaller overall area and/or increased frontside metal routing flexibility.

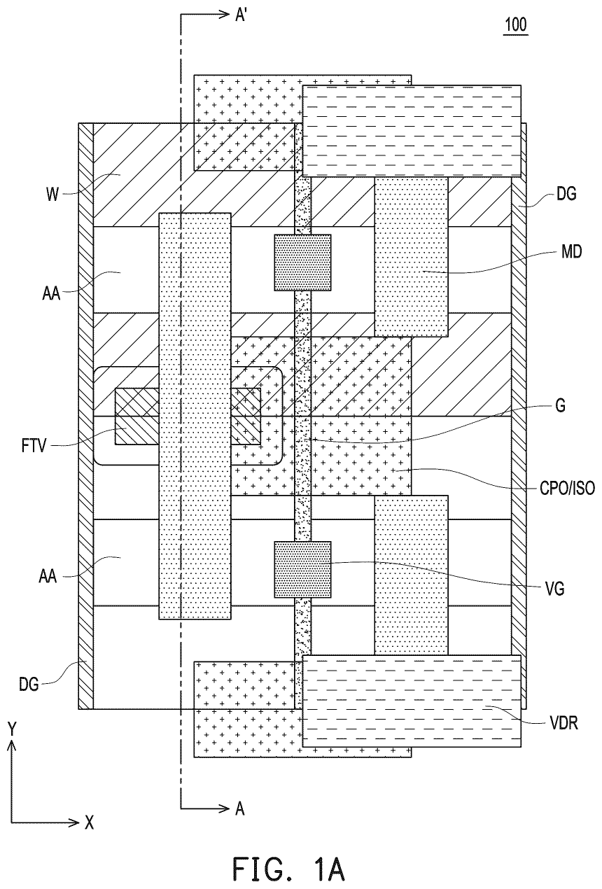

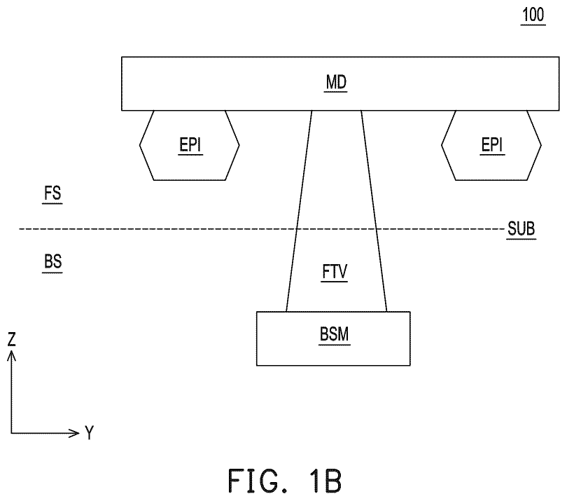

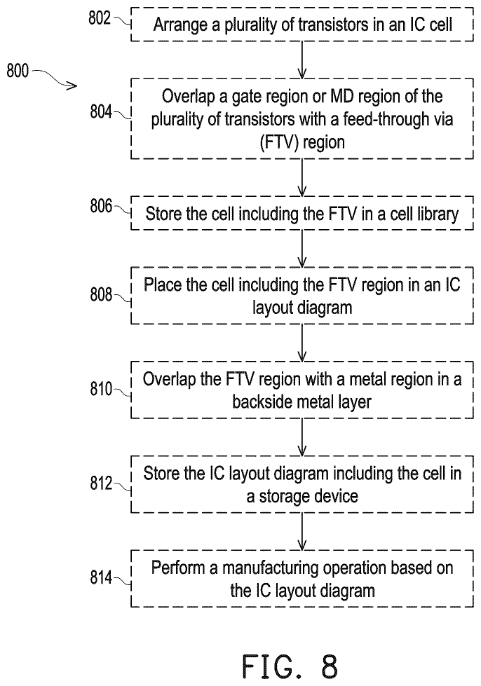

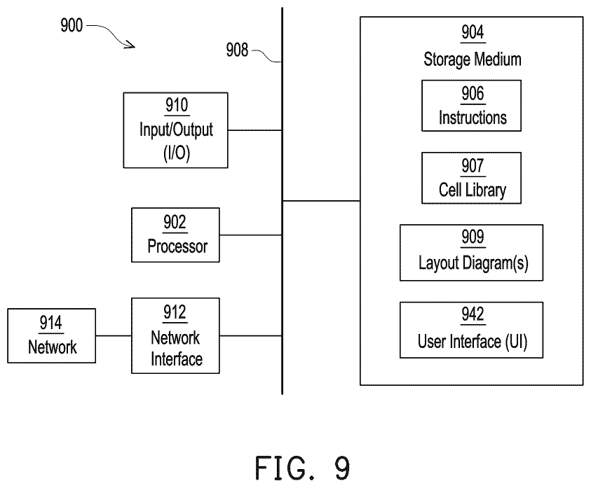

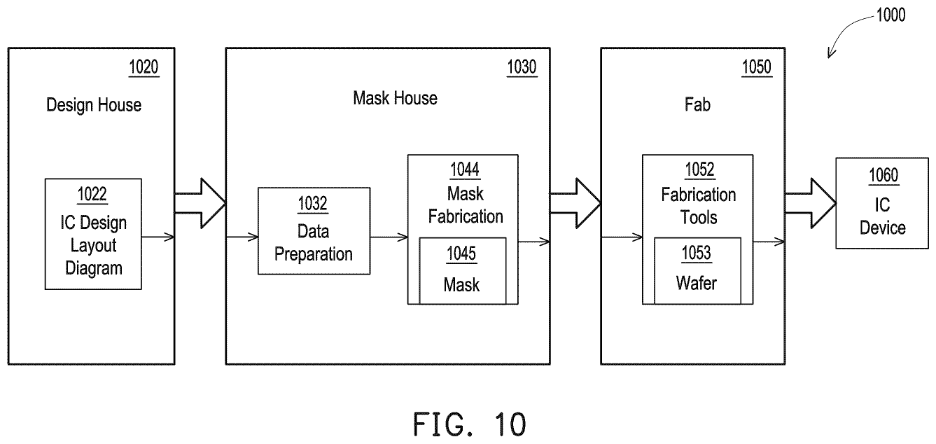

As discussed below, in accordance with various embodiments, FIGS. 1A-6D depict schematic diagrams and plan and cross-sectional views of IC devices/layout diagrams 100-600D including FTVs, FIG. 7 is a flowchart of a method 700 of manufacturing an IC device, e.g., IC device 100-600D, based on a corresponding one or more of IC layout diagrams 100-600D, FIG. 8 is a flowchart of a method 800 of generating one or more of IC layout diagrams 100-600D, e.g., using a system 900 discussed below with respect to FIG. 9 and/or, e.g., in accordance with an IC manufacturing flow associated with an IC manufacturing system 1000 discussed below with respect to FIG. 10.

Each of the figures herein, e.g., FIGS. 1A-6D, is simplified for the purpose of illustration. The figures are views of IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, bulk connections, or other transistor elements, isolation structures, or the like, in addition to the features depicted in FIGS. 1A-6D.

In each of IC devices/layout diagrams 1A-6D, some or all of the reference designators represent both IC device features and the IC layout features used to at least partially define the corresponding IC device features in a manufacturing process, e.g., method 700 discussed below with respect to FIG. 7 and/or the IC manufacturing flow associated with IC manufacturing system 1000 discussed below with respect to FIG. 10. Accordingly, each of IC devices/layout diagrams 100-600D represents a view of both an IC layout diagram 100-600D and a corresponding IC device 100-600D.

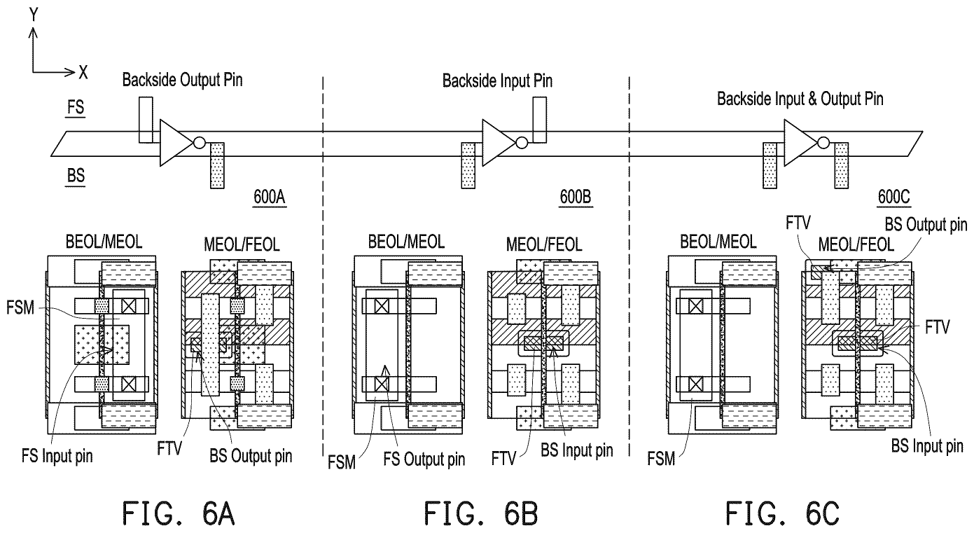

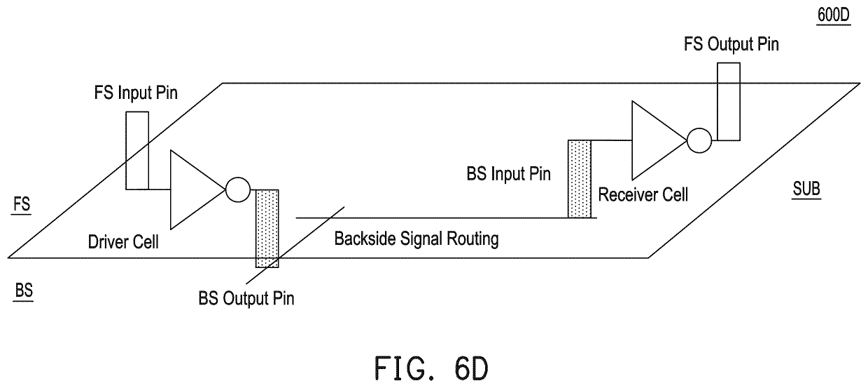

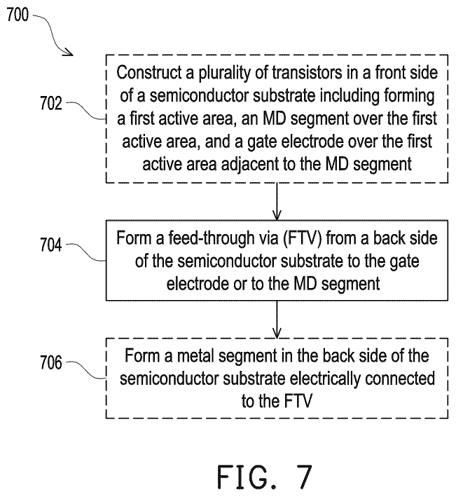

In some embodiments, an IC device/layout diagram 100-600C corresponds to an IC cell, e.g., corresponding to an inverter, buffer, or logic gate, including a plurality of transistors isolated from adjacent elements by a pair of dummy gates, as discussed below. In some embodiments, an IC device/layout diagram 600D depicted in FIG. 6D corresponds to multiple cells as discussed below.

Each of IC layout diagrams/devices 100-600D discussed below includes arrangements of some or all of at least one of a semiconductor substrate, a well, an active region/area, a S/D region/structure, an MD region/segment, a cut MD region, a gate region/structure, a cut gate region, an isolation feature/structure, a metal region/segment, a via region/structure, and/or an FTV region/structure, each discussed below.

A semiconductor substrate, e.g., a substrate SUB, is a portion, e.g., a die, or all of a semiconductor wafer, e.g., a silicon (Si) wafer, or an epitaxial Si layer, suitable for forming one or more IC devices, e.g., IC devices 100-600D. In each of the embodiments discussed below, a semiconductor substrate includes a front side, e.g., front side FS, within which a first subset of the features of the IC devices are formed through a first set of manufacturing processes, e.g., front-end-of-line (FEOL) processes, middle-end-of-line (MEOL) processes, and back-end-of-line (BEOL) processes, and a back side, e.g., back side BS, within which a second subset of the features of the IC devices are formed through a second set of manufacturing processes, e.g., backside metallization processes, performed after the first set of manufacturing processes are performed.

In some embodiments, the semiconductor substrate is thinned by performing one or more thinning operations between the first and second sets of manufacturing operations. In some embodiments, the front and back sides are separated by a plane extending in X and Y directions.

A well, e.g., a well W, is a continuous portion of the semiconductor substrate including one or more dopants. In various embodiments, a well is a p-well based on the semiconductor substrate portion including one or more acceptor dopants, e.g., boron (B) or aluminum (Al), or an n-well based on the semiconductor substrate portion including one or more donor dopants, e.g., phosphorous (P) or arsenic (As).

An active region/area, e.g., active region/area AA, is a region in an IC layout diagram included in a manufacturing process as part of defining an active area, also referred to as an oxide diffusion or definition (OD), in the semiconductor substrate, either directly or in an n-well or p-well region/area, in which one or more IC device features, e.g., a S/D structure, is formed. In some embodiments, an active area is an n-type or p-type active area of a planar transistor, a FinFET, or a GAA transistor. In various embodiments, an active area (structure) includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material.

In some embodiments, an active area is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

A S/D region/structure, e.g., a S/D region/structure EPI, is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a planar FET, a fin structure of a FinFET, or a gate structure of a GAA transistor. In some embodiments, a S/D region/structure includes one or more portions having doping concentrations greater than one or more doping concentrations present in the corresponding channel feature. In some embodiments, a S/D region/structure includes one or more epitaxial regions of a semiconductor material, e.g., Si, SiGe, and/or silicon-carbide SiC.

An MD region/segment, e.g., MD region/segment MD, is a conductive region in the IC layout diagram included in the manufacturing process as part of defining an MD segment, also referred to as a conductive segment or MD conductive line or trace, in and/or on the semiconductor substrate. In some embodiments, an MD region overlaps an active area at a location of a S/D region in the IC layout diagram, and the corresponding MD segment contacts and is electrically connected to the S/D structure of the active area.

In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of the semiconductor substrate and/or an epitaxial layer having a doping level, e.g., based on an implantation process, sufficient to cause the segment to have the low resistance level. In various embodiments, a doped MD segment includes one or more dopant materials having doping concentrations of about 1*1016 per cubic centimeter (cm⁻³) or greater.

In some embodiments, a manufacturing process includes two MD layers, and an MD region/segment, e.g., MD region/segment MD, refers to both of the two MD layers in the manufacturing process.

A cut MD region, e.g., a cut MD region CMD, is a region in the IC layout diagram included in the manufacturing process as part of defining a portion of an MD segment that is removed and replaced with one or more dielectric materials, e.g., an isolation structure ISO, in operations performed subsequent to the MD segment formation, thereby electrically isolating the adjacent portions of the MD segment from each other.

A gate region/structure, e.g., a gate region/structure G or DG, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided to an adjacent gate dielectric layer.

A gate dielectric layer, e.g., a gate dielectric layer of a gate structure G or DG, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In some embodiments, a gate region/structure corresponds to a dummy gate region/structure, e.g., dummy gate region/structure DG. In some embodiments, a dummy gate region/structure includes a gate electrode electrically connected, e.g., tied-off, to one or more features, e.g., a power rail or other metal segment or an adjacent instance of a S/D region/structure such that a transistor corresponding to the dummy gate region/structure and overlapping/underlying active region/area is switched off by design. In some embodiments, a dummy gate region/structure that overlaps/overlies an edge of an active region/area is referred to as a continuous poly on oxide definition edge (CPODE) region/structure.

A cut gate region, e.g., a cut gate region CPO, also referred to as a cut poly region in some embodiments, is a region in the IC layout diagram included in the manufacturing process as part of defining a portion of a gate electrode that is removed and replaced with one or more dielectric materials, e.g., an isolation structure ISO, in operations performed subsequent to the gate electrode formation, thereby electrically isolating the adjacent portions of the gate electrode from each other.

An isolation feature/structure, e.g., isolation feature/structure ISO, is a feature including one or more regions in the IC layout diagram included in the manufacturing process as part of defining an isolation structure configured to electrically isolate adjacent features from each other, e.g., adjacent gate electrode portions based on a cut gate region of the IC layout diagram. In some embodiments, an isolation feature/structure, e.g., isolation feature/structure ISO, includes a dielectric region/volume positioned between adjacent features, e.g., MD regions/segments MD or gate regions/structures G or DG, corresponding to a cutting process, e.g., a cut MD or cut gate process. A dielectric region is a region in the IC layout diagram included in the manufacturing process as part of defining a volume including one or more insulating materials.

A metal line or region, e.g., a frontside metal region/segment FSM or backside metal region/segment BSM, is a region in the IC layout diagram included in the manufacturing process as part of defining a metal line structure, or segment, including one or more conductive materials, e.g., polysilicon, copper (Cu), aluminum (Al), tungsten (W), cobalt (Co), ruthenium (Ru), or one or more other metals or other suitable materials, in a given frontside or backside metal layer of the manufacturing process.

In some embodiments, a metal region/segment corresponds to a first frontside metal layer (also referred to as a metal zero layer MO or frontside metal zero layer MO in some embodiments), or a second or higher level frontside metal layer of the manufacturing process. In some embodiments, a second frontside metal layer is referred to as a metal one layer or frontside metal one layer.

In some embodiments, a metal region/segment corresponds to a first backside metal layer (also referred to as a backside metal zero layer BMO in some embodiments), or a second or higher level backside metal layer of the manufacturing process. In some embodiments, a second backside metal layer is referred to as a backside metal one layer.

In some embodiments, a metal region/segment, e.g., a power rail, corresponds to a component of a power distribution network configured to distribute one or both of a power supply voltage, e.g., a power supply voltage VDD, and a reference or ground voltage, e.g., a reference voltage VSS. The power distribution network component is electrically connected to one or more features, e.g., additional metal regions/segments, via regions/structures, and/or FTV regions/structures, configured to distribute the corresponding power supply or reference voltage and be electrically isolated from IC components outside the distribution network.

In some embodiments, a metal region/segment corresponds to a signal line included in a signal path configured to electrically connect a first device or circuit output terminal, e.g., a S/D region/structure, to one or more second device or circuit input terminals, e.g., one or more gate electrodes. The signal line is electrically connected to one or more features, e.g., additional metal regions/segments, via regions/structures, and/or FTV regions/structures, configured to propagate a signal from the output terminal to the input terminal and be electrically isolated from IC components outside the signal path.

A via region/structure, e.g., a via region/structure VG, VDR, VIA0, or VB, is a region in the IC layout diagram included in the manufacturing process as part of defining a via structure including one or more conductive materials configured to provide an electrical connection between a first, e.g., overlying, conductive structure, e.g., a metal segment FSM and a second, e.g., underlying, conductive structure, e.g., a metal segment FSM, a gate electrode of a gate structure G or DG, an instance of MD segment MD, or a S/D structure such as an instance of S/D structure EPI, aligned with the first conductive structure in the Z direction.

In some embodiments, a via region/structure VG corresponds to the underlying conductive structure being the gate electrode of a gate region/structure G or DG, a via region/structure VDR corresponds to the underlying conductive structure being a S/D region/structure or MD region/segment MD and the overlying conductive structure being a frontside metal region/segment FSM corresponding to a power distribution network, and/or a via region/structure VIA0 corresponds to the underlying and overlying conductive structures being instances of frontside metal region/segment FSM corresponding to respective first and second frontside metal layers.

In some embodiments, a via region/structure, e.g., via region/structure VB, also referred to as a backside via region/structure VB in some embodiments, corresponds to an electrical connection between the first conductive structure being a backside conductive structure, e.g., a first instance of backside metal region/segment BSM or an active area AA, and the second conductive structure being a backside conductive structure, e.g., a second instance of backside metal region/segment BSM.

In some embodiments, a via region/structure, e.g., a backside via region/structure VB, has one or more cross-sectional dimensions that correspond to, e.g., are approximately equal to, one or more cross-sectional dimensions of the overlying and/or underlying region/structure, e.g., a dimension in a first one of the X or Y direction such as a length or width that matches a dimension in the same one of the X or Y direction of one of the overlying or underlying region/structure, e.g., a corresponding length or width. In some embodiments, a backside via region/structure VB has a cross-sectional dimension approximately equal to a width of an overlying active region/area AA and/or S/D region/structure, e.g., S/D region/structure EPI. In some embodiments, a backside via region/structure VB has a cross-sectional dimension approximately equal to a width of an overlying MD region/segment MD.

An FTV region/structure, e.g., an instance of FTV, is a region in the IC layout diagram included in the manufacturing process as part of defining an FTV structure including one or more conductive materials configured to provide an electrical connection between a first, e.g., overlying, conductive structure, e.g., a metal segment FSM, an MD segment MD, a gate electrode of a gate structure G or DG, and a second, e.g., underlying, conductive structure, e.g., a metal segment BSM, positioned in a backside metal layer and aligned with the first conductive structure in the Z direction. In some embodiments, the underlying conductive structure is a signal line or a power distribution component such as a power rail.

In some embodiments, an FTV region/structure, e.g., an FTV, has one or more cross-sectional dimensions greater than one or more cross-sectional dimensions of the overlying and/or underlying region/structure, e.g., a dimension in a first one of the X or Y direction such as a length or width greater than a dimension in the same one of the X or Y direction of one of the overlying or underlying region/structure, e.g., a corresponding length or width. In some embodiments, an FTV has a cross-sectional dimension greater than a width of an overlying MD region/structure or a width of an overlying gate structure G or DG.

In some embodiments, an FTV has one or both cross-sectional dimensions that extend beyond the corresponding MD region/structure or gate structure G or DG in one or both of a width or length direction. In some embodiments, an FTV has a cross-sectional dimension that spans multiple instances of an overlying region/structure, e.g., multiple instances of MD region/segment MD or gate region/structure G or DG.

FIG. 1A depicts a frontside plan view of IC device/layout diagram 100 and the X and Y directions, and FIG. 1B depicts a cross-sectional view of IC device/layout diagram 100 and the Y and Z directions and corresponds to the line A-A′ in FIG. 1A, in accordance with some embodiments.

IC device/layout diagram 100 includes well W configured as an n-well positioned in front side FS of substrate SUB, a p-type active region/area AA positioned in well W, an n-type active region/area AA positioned in front side FS, instances of MD region/segment MD overlapping/overlying the instances of active region/area AA at positions corresponding to instances of S/D region/structure EPI, instances of via region/structure VDR overlapping/overlying instances of MD region/segment MD and configured to be electrically connected to corresponding power supply and reference voltage distribution networks, a gate region/structure G, cut gate regions CPO corresponding to isolation structures ISO, instances of via region/structure VG overlapping/overlying corresponding portions of gate region/structure G, each positioned between instances of dummy gate region/structure DG.

IC device/layout diagram 100 also includes FTV region/structure FTV positioned between the instances of dummy gate region/structure DG and overlapping/directly contacting an instance of MD region/segment MD. FTV region FTV also overlaps backside metal region BSM and thereby corresponds to FTV structure FTV extending into back side BS of substrate SUB and being electrically connected to, e.g., directly contacting, backside metal segment BSM.

In the embodiment depicted in FIGS. 1A and 1B, IC device/layout diagram 100 is configured as an inverter, via regions/structures VG are configured as input terminals, backside metal region/segment BSM corresponds to a signal line, and FTV region/structure FTV is configured as an output terminal electrically connected to the signal line.

By including FTV region/structure FTV configured as an output terminal electrically connected to a backside signal line and directly contacting MD region/segment MD, IC device/layout diagram 100 is configured to use fewer frontside resources than approaches in which output terminals use frontside resources, thereby enabling increased frontside routing flexibility.

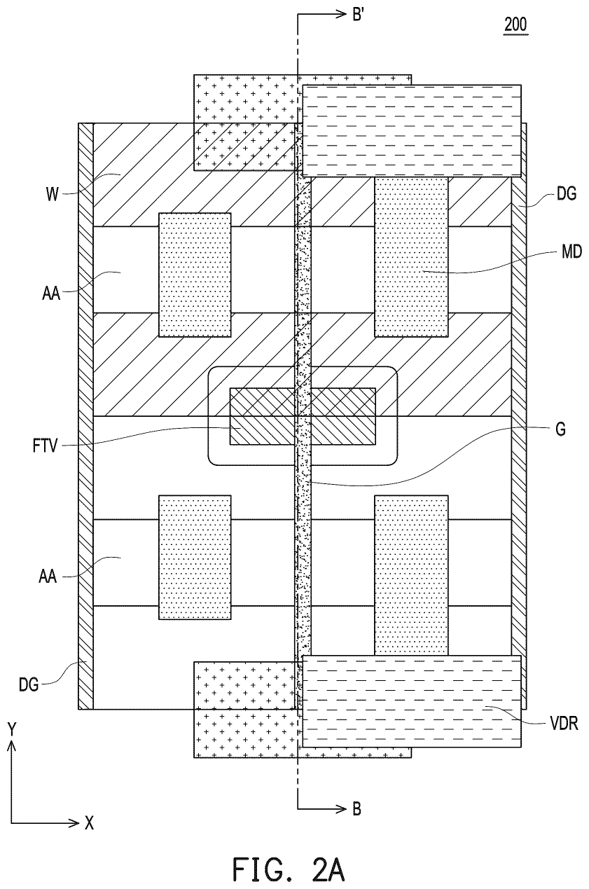

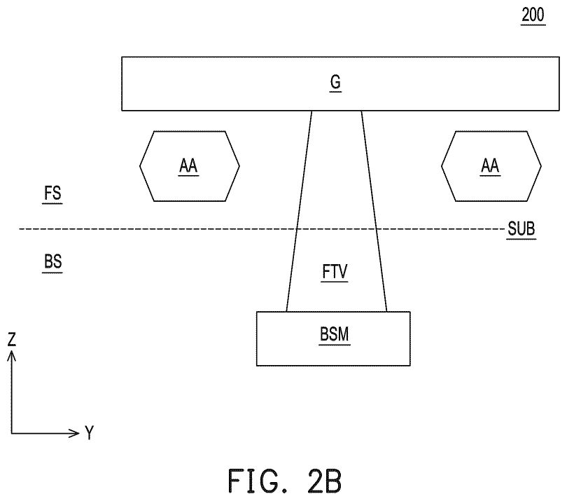

FIG. 2A depicts a frontside plan view of IC device/layout diagram 200 and the X and Y directions, and FIG. 2B depicts a cross-sectional view of IC device/layout diagram 200 and the Y and Z directions and corresponds to the line B-B′ in FIG. 2A, in accordance with some embodiments.

IC device/layout diagram 200 is configured as an inverter including a feature arrangement similar to that of IC device/layout diagram 100 (not all features depicted for the purpose of clarity) except that FTV region/structure overlaps/directly contacts gate region/structure G instead of an instance of MD region/segment MD. IC device/layout diagram 200 also does not include the instance of cut gate region CPO corresponding to isolation structure ISO positioned between the instances of active region/area AA and included in IC device/layout diagram 100 to electrically isolate FTV structure FTV from the gate electrodes of the resultant portions of gate structure G.

IC device/layout diagram 200 thereby includes FTV region/structure FTV configured as an input terminal electrically connected to backside metal region/segment BSM configured as a signal line, and is thereby configured to use fewer frontside resources than approaches in which input terminals use frontside resources, thereby enabling increased frontside routing flexibility.

IC devices/layout diagrams 100 and 200 are non-limiting examples of IC cells/devices configured as inverters including FTVs configured as input or output terminals. In various embodiments, IC cells/devices are otherwise configured, e.g., as buffers, logic gates, latches, or the like, including FTVs configured as input and/or output terminals by directly contacting gate regions/structures G and/or MD regions/segments MD, e.g., positioned between instances of dummy gate regions/structures DG, and are thereby configured to use fewer frontside resources than other approaches and enable the benefits discussed above with respect to IC devices/layout diagrams 100 and 200.

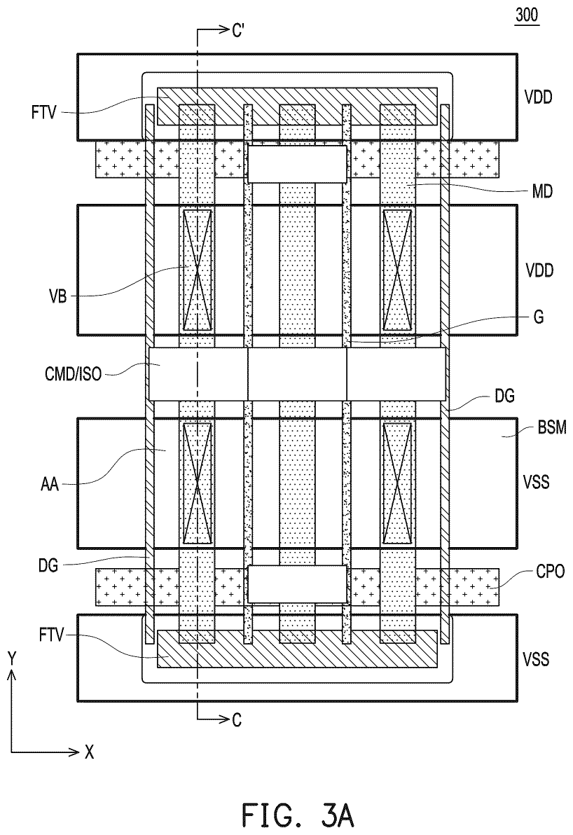

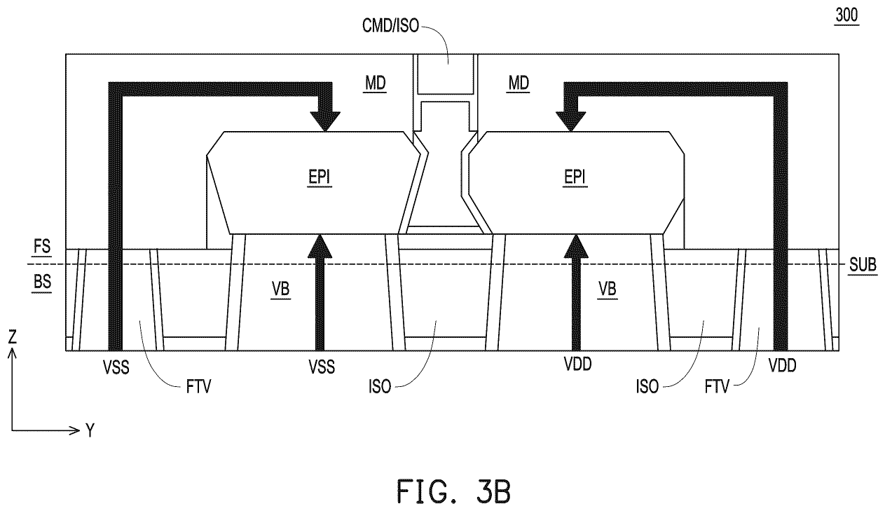

FIG. 3A depicts a frontside plan view of IC device/layout diagram 300 and the X and Y directions, and FIG. 3B depicts a cross-sectional view of IC device/layout diagram 300 and the Y and Z directions and corresponds to the line C-C′ in FIG. 3A, in accordance with some embodiments.

IC device/layout diagram 300 includes instances of active region/area AA positioned in front side FS of substrate SUB, instances of MD region/segment MD overlapping/overlying the instances of active region/area AA at positions corresponding to instances of S/D region/structure EPI, instances of cut MD region CMD corresponding to isolation structures ISO, instances of backside via region/structure VB overlapping/underlying instances of MD region/segment MD at the positions corresponding to instances of S/D region/structure EPI, instances of gate region/structure G, and cut gate regions CPO corresponding to isolation structures ISO, each positioned between instances of dummy gate region/structure DG. Additional features are not depicted for the purpose of clarity.

IC device/layout diagram 300 also includes two instances of FTV region/structure FTV positioned between the instances of dummy gate region/structure DG and overlapping/directly contacting corresponding instances of MD region/segment MD. The instances of FTV region FTV also overlap instances of backside metal region BSM and thereby correspond to FTV structures FTV extending into back side BS of substrate SUB and being electrically connected to, e.g., directly contacting, the corresponding instances of backside metal segment BSM.

A first instance of FTV region/structure FTV is positioned adjacent to a first instance of backside via/structure VB (separated by an isolation region/structure ISO), each configured to electrically connect the corresponding overlying feature (MD region/segment MD or S/D region/structure EPI) to a corresponding instance of backside metal region/segment BSM configured as a component of a power supply voltage VDD distribution network. A second instance of FTV region/structure FTV is positioned adjacent to a second instance of backside via/structure VB (separated by an isolation region/structure ISO), each configured to electrically connect the corresponding overlying feature (MD region/segment MD or S/D region/structure EPI) to a corresponding instance of backside metal region/segment BSM configured as a component of a reference voltage VSS distribution network.

IC device/layout diagram 300 is thereby configured as a cell/device including a dual power rail connection scenario in which parallel VDD and VSS paths enable lower path resistance, voltage drops, and power loss without using frontside resources compared to approaches including frontside power and/or reference connections. IC device/layout diagram 300 is configured to use fewer frontside resources than approaches in which power connections use frontside resources, thereby enabling increased frontside routing flexibility.

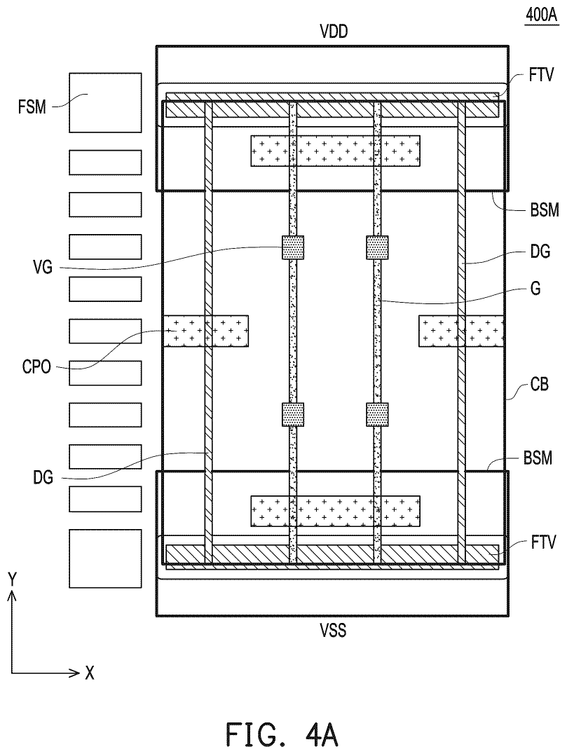

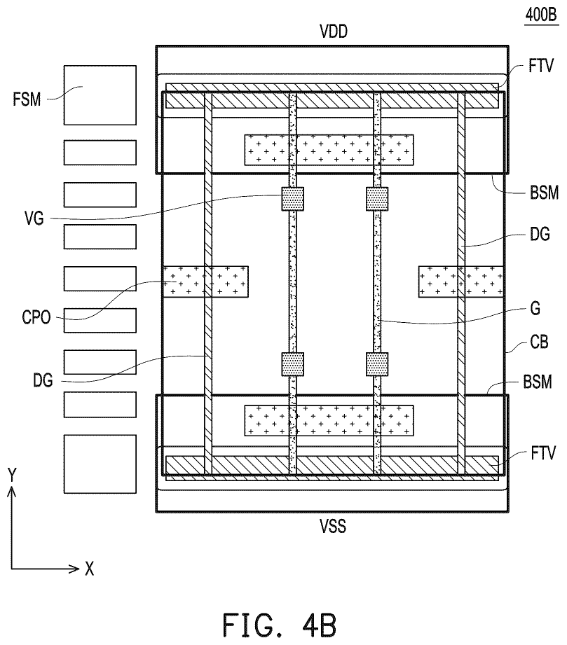

FIG. 4A depicts a frontside plan view of IC device/layout diagram 400A and the X and Y directions, and FIG. 4B depicts a frontside plan view of IC device/layout diagram 400B and the X and Y directions, in accordance with some embodiments.

Each of IC device/layout diagram 400A and 400B includes instances of gate region/structure G, cut gate region CPO, via region/structure VG, and other features not depicted for the purpose of clarity positioned between instances of dummy gate region/structure DG and within a cell boundary CB. Each of FIGS. 4A and 4B also depicts instances of frontside metal region/segment FSM and backside metal region/segment BSM.

Each of IC device/layout diagram 400A and 400B includes two instances of FTV region/structure FTV configured to directly contact overlapping/overlying instances of gate region/structure G and dummy gate region/structure DG and be electrically connected to corresponding instances of backside metal region/segment BSM configured as components of power supply voltage VDD and reference voltage VSS distribution networks.

Each of IC device/layout diagram 400A and 400B corresponds to instances of active region/area AA extending across corresponding instances of dummy gate region/structure DG that act to isolate the adjacent portions of the active region/area AA by being tied off to an appropriate one of power supply voltage VDD or reference voltage VSS. By including the instances of FTV region/structure FTV configured as depicted in FIGS. 4A and 4B, the instances of dummy gate region/structure DG are tied off without using frontside resources.

As depicted in FIG. 4A, IC device/layout diagram 400A has a height in the Y direction corresponding to eleven instances of frontside metal region/segment FSM, each of which is thereby available for signal routing. Compared to approaches in which frontside resources are used for power supply and/or reference voltage distribution, a greater number of instances of frontside metal region/segment FSM are thereby available.

As depicted in FIG. 4B, IC device/layout diagram 400B has a height in the Y direction corresponding to nine instances of frontside metal region/segment FSM, each of which is thereby available for signal routing. Compared to approaches in which frontside resources are used for power supply and/or reference voltage distribution, IC device/layout diagram 400B requires a smaller height and thereby area to enable the use of nine instances of frontside metal region/segment FSM for signal routing.

The numbers of instances of frontside metal region/segment FSM corresponding to the heights in the Y direction are non-limiting examples provided for the purpose of illustration. Other numbers of instances of frontside metal region/segment FSM corresponding to the heights in the Y direction are within the scope of the present disclosure.

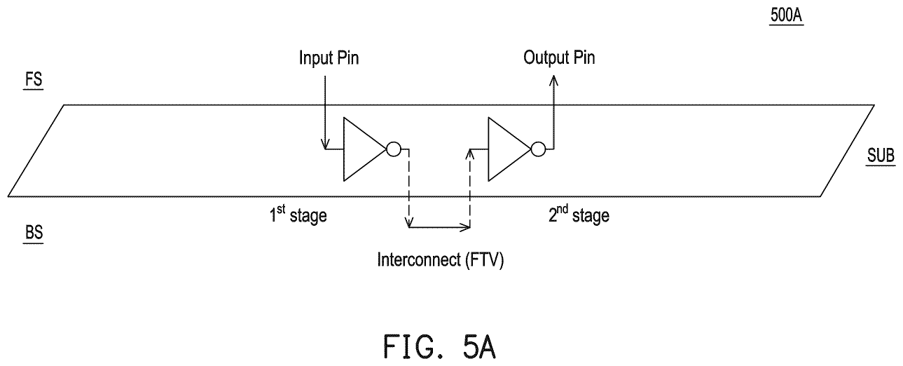

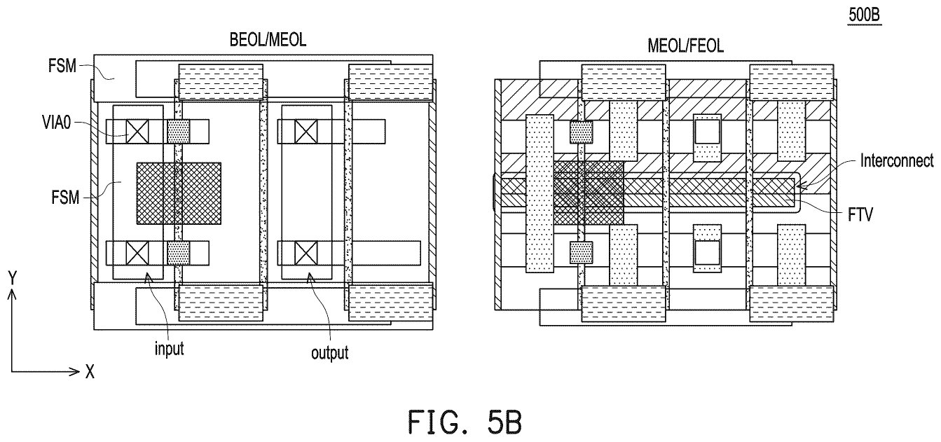

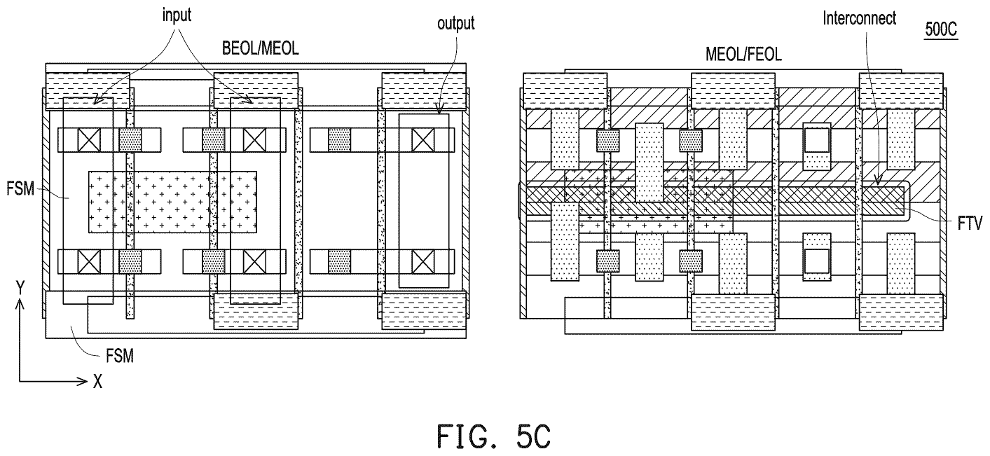

FIG. 5A depicts a schematic view of IC device/layout diagram 500A, FIG. 5B depicts a plan view of IC device/layout diagram 500B and the X and Y directions, and FIG. 5C depicts a plan view of IC device/layout diagram 500C and the X and Y directions, in accordance with some embodiments.

As depicted in FIG. 5A, IC device/layout diagram 500A is a circuit including first and second stages, e.g., inverters. The first stage includes an input pin positioned in front side FS of substrate SUB, the second stage includes an output pin positioned in front side FS, and the first and second stages are electrically connected to each other through a TSV interconnect extending from front side FS to back side BS of substrate SUB.

In the embodiment depicted in FIG. 5B, IC device/layout diagram 500B is a buffer circuit including instances of front side metal region/segment FSM configured as input/output pins, instances of via region/structure VIA0, three instances of gate region/structure G, and additional features (not labeled for the purpose of clarity) arranged between instances of dummy gate region/structure DG as the first and second stages corresponding to inverters.

In the embodiment depicted in FIG. 5C, IC device/layout diagram 500C is an AND/OR gate including instances of front side metal region/segment FSM configured as input/output pins, four instances of gate region/structure G, and additional features (not labeled for the purpose of clarity) arranged between instances of dummy gate region/structure DG as the first and second stages.

In each of IC device/layout diagram 500B and 500C, an FTV region/structure FTV is positioned between the instances of dummy gate region/structure DG and configured as an interconnect between the output terminal of the first stage and the input terminal of the second stage.

Each of IC device/layout diagram 500A, 500B, and 500C is a non-limiting example of a multistage circuit including an FTV region/structure FTV configured as an interconnect between stages, thereby enabling the use of frontside resources for signal routing having greater flexibility, and in some embodiments lower parasitic capacitance, than approaches in which interconnects use frontside resources. Multistage circuits including FTV interconnects, e.g., more than one FTV, other than those depicted in FIGS. 5A-5C are within the scope of the present disclosure.

FIGS. 6A-6C depict plan views of respective IC device/layout diagram 600A-600C and the X and Y directions, and FIG. 6D depicts a schematic view of IC device/layout diagram 600D, in accordance with some embodiments.

IC device/layout diagram 600A is an embodiment of IC device/layout diagram 100 discussed above including an instance of frontside metal region/segment FSM configured as a frontside input pin and an FTV configured as a backside output pin, and IC device/layout diagram 600B is an embodiment of IC device/layout diagram 200 discussed above including an instance of frontside metal region/segment FSM configured as a frontside output pin and an FTV configured as a backside input pin.

IC device/layout diagram 600C is configured as an inverter including two instances of FTV region/structure FTV, one configured as a backside input pin, and the other configured as a backside output pin. By using the instances of FTV for both the input and output pins, IC device/layout diagram 600C further reduces the use of frontside resources compared to IC device/layout diagram 600A and 600B, each of which thereby enables the benefits discussed above with respect to IC device/layout diagram 100 and 200.

IC device/layout diagram 600D is a circuit including a driver cell, e.g., an instance of IC device/layout diagram 600A, and a receiver cell, e.g., an instance of IC device/layout diagram 600B, and a backside signal routing path, e.g., including instances of backside metal region/segment BSM, that electrically connects the backside output pin (FTV) of the driver cell to the backside input pin (FTV) of the receiver cell.

By including the driver and receiver cells including respective backside output and input FTV pins and corresponding backside signal routing path, IC device/layout diagram 600D is capable of realizing the benefits discussed above with respect to IC device/layout diagram 100, 200, and 600A-600C.

The embodiments depicted in FIGS. 6A-6D are non-limiting examples provided for the purpose of illustration. Other circuit types and configurations including combinations of backside output and input FTV pins are within the scope of the present disclosure.

FIG. 7 is a flowchart of method 700 of manufacturing an IC device, in accordance with some embodiments. Method 700 is operable to form some or all of one or more of IC devices 100-600D discussed above with respect to FIGS. 1A-6D.

In some embodiments, performing some or all of the operations of method 700 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor wafer.

In some embodiments, the operations of method 700 are performed in the order depicted in FIG. 7. In some embodiments, the operations of method 700 are performed in an order other than the order depicted in FIG. 7. In some embodiments, one or more additional operations are performed before, during, and/or after the operations of method 700. In some embodiments, performing some or all of the operations of method 700 includes performing one or more operations as discussed below with respect to IC manufacturing system 1000 and FIG. 10.

At operation 702, a plurality of transistors is constructed in a front side of a semiconductor substrate, constructing the transistors including forming an active area extending in a first direction, an MD segment overlying the active area and extending in a second direction perpendicular to the first direction, and forming a first gate electrode overlying the active area and extending in the second direction adjacent to the MD segment. In some embodiments, constructing the plurality of transistors includes forming active region/area AA, an MD segment MD, and gate structure G corresponding to one of IC devices 100-600D discussed above with respect to FIGS. 1A-6D.

In some embodiments, constructing the plurality of transistors including forming the active area, MD segment, and gate electrode includes performing a plurality of manufacturing processes including one or more of a lithography, diffusion, implantation, deposition, etching, planarizing, or other operation suitable for constructing the plurality of transistors including features arranged as discussed above with respect to FIGS. 1A-6D.

At operation 704, an FTV is formed from the back side of the semiconductor substrate to the gate electrode or MD segment. In some embodiments, forming the FTV includes forming one or more instances of FTV structure FTV configured as discussed above with respect to FIGS. 1A-6D.

In some embodiments, forming an FTV includes performing a plurality of manufacturing operations including depositing and patterning one or more photoresist layers, performing one or more etching processes, and performing one or more deposition processes whereby one or more conductive materials are configured to form a continuous, low resistance structure from the corresponding front side feature to the back side of the semiconductor substrate.

At operation 706, in some embodiments, a metal segment is formed in the back side of the semiconductor substrate electrically connected to the FTV. In some embodiments, forming the backside metal segment includes forming one or more instances of backside metal segment BSM electrically connected to a corresponding one or more FTVs and configured as discussed above with respect to FIGS. 1A-6D.

In some embodiments, forming a backside metal segment includes performing a plurality of manufacturing operations including depositing and patterning one or more photoresist layers, performing one or more etching processes, and performing one or more deposition processes whereby one or more conductive materials are configured to form a continuous, low resistance backside structure.

By performing some or all of the operations of method 700, an IC device is manufactured in which an FTV directly contacts a frontside gate electrode or MD segment and extends into the back side of a semiconductor substrate, thereby enabling the realization of the benefits discussed above with respect to IC devices 100-600D.

FIG. 8 is a flowchart of method 800 of generating an IC layout diagram, e.g., one or more of IC layout diagrams 100-600D discussed above with respect to FIGS. 1A-6D, in accordance with some embodiments.

In some embodiments, generating the IC layout diagram includes generating the IC layout diagram corresponding to an IC device, e.g., IC device 100-600D discussed above with respect to FIGS. 1A-6D, manufactured based on the generated IC layout diagram.

In some embodiments, some or all of method 800 is executed by a processor of a computer, e.g., a processor 902 of an IC layout diagram generation system 900, discussed below with respect to FIG. 9.

Some or all of the operations of method 800 are capable of being performed as part of a design procedure performed in a design house, e.g., a design house 1020 discussed below with respect to FIG. 10.

In some embodiments, the operations of method 800 are performed in the order depicted in FIG. 8. In some embodiments, the operations of method 800 are performed simultaneously and/or in an order other than the order depicted in FIG. 8. In some embodiments, one or more operations are performed before, between, during, and/or after performing one or more operations of method 800.

At operation 802, in some embodiments, a plurality of transistors is arranged in an IC cell, the plurality of transistors including an active region, a gate region overlapping the active region, and an MD region overlapping the active region adjacent to the gate region. In some embodiments, arranging the plurality of transistors includes arranging the plurality of transistors including active region AA, gate region G, and MD region MD configured in accordance with an IC layout diagram 100-600C as discussed above with respect to FIGS. 1A-6D.

At operation 804, in some embodiments, the gate region or MD region is overlapped with an FTV region. In some embodiments, overlapping the gate region or MD region with the FTV region includes overlapping tone or more gate regions and/or MD regions with one or more corresponding instances of FTV region FTV in accordance with an IC layout diagram 100-600C as discussed above with respect to FIGS. 1A-6D.

At operation 806, in some embodiments, the cell including the FTV region is stored in a cell library. In some embodiments, storing the cell includes storing one of IC layout diagrams 100-600C discussed above with respect to FIGS. 1A-6C.

In some embodiments, storing the cell in the cell library includes storing the cell in a non-volatile, computer-readable memory or a database and/or includes storing the cell over a network. In some embodiments, storing the cell in the cell library includes storing the cell in cell library 907 and/or over network 914 of IC layout diagram generation system 900, discussed below with respect to FIG. 9

At operation 808, in some embodiments, the cell including the FTV region is placed in an IC layout diagram. In some embodiments, placing the cell in the IC layout diagram includes placing one or more of IC layout diagrams 100-600C in an IC layout diagram, e.g., IC layout diagram 600D discussed above with respect to FIG. 6D.

At operation 810, in some embodiments, the FTV region is overlapped with a metal region in a backside metal layer. In some embodiments, overlapping the FTV region with the metal region includes overlapping one or more instances of FTV region FTV with corresponding one or more instances of backside metal region BSM arranged in accordance with one or more of IC layout diagrams 100-600D as discussed above with respect to FIGS. 1A-6D.

At operation 812, in some embodiments, the IC layout diagram including the cell (including the FTV region) is stored in a storage device. In some embodiments, storing the IC layout diagram in the storage device includes storing one or more of IC layout diagrams 100-600D, discussed above with respect to FIGS. 1A-6D, in the storage device.

In some embodiments, storing the IC layout diagram in the storage device includes storing the IC layout diagram in a non-volatile, computer-readable memory or a database, and/or includes storing the IC layout diagram over a network. In some embodiments, storing the IC layout diagram in the storage device includes storing the IC layout diagram in layout diagrams 909 and/or over network 914 of IC layout diagram generation system 900, discussed below with respect to FIG. 9.

At operation 814, in some embodiments, one or more manufacturing operations, one or more lithographic exposures, are performed based on the IC layout diagram. Non-limiting examples of performing one or more manufacturing operations, e.g., one or more lithographic exposures, based on the IC layout diagram are discussed above with respect to FIG. 7 and below with respect to FIG. 10.

By executing some or all of the operations of method 800, an IC layout diagram is generated corresponding to an IC device in which an FTV directly contacts a frontside gate electrode or MD segment and extends into the back side of a semiconductor substrate, thereby enabling the realization of the benefits discussed above with respect to IC devices 100-600D.

FIG. 9 is a block diagram of IC layout diagram generation system 900, in accordance with some embodiments. Methods described herein of designing IC layout diagrams in accordance with one or more embodiments are implementable, for example, using IC layout diagram generation system 900, in accordance with some embodiments.

In some embodiments, IC layout diagram generation system 900 is a general purpose computing device including a hardware processor 902 and a non-transitory, computer-readable storage medium 904. Storage medium 904, amongst other things, is encoded with, i.e., stores, computer program code 906, i.e., a set of executable instructions. Execution of instructions 906 by hardware processor 902 represents (at least in part) an electronic design automation (EDA) tool which implements a portion or all of a method, e.g., method 1500 of generating an IC layout diagram described above with respect to FIG. 15 (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 906 encoded in computer-readable storage medium 904 in order to cause IC layout diagram generation system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, computer-readable storage medium 904 stores computer program code 906 configured to cause IC layout diagram generation system 900 (where such execution represents (at least in part) the EDA tool) to be usable for performing a portion or all of the noted processes and/or methods. In one or more embodiments, computer-readable storage medium 904 also stores information which facilitates performing a portion or all of the noted processes and/or methods.

In one or more embodiments, computer-readable storage medium 904 stores cell library 907 of cells including such cells as disclosed herein, e.g., IC layout diagrams 100-600C discussed above with respect to FIGS. 1A-6D.

In one or more embodiments, computer-readable storage medium 904 stores layout diagrams 909 including such IC layout diagrams as disclosed herein, e.g., IC layout diagrams 100-600C and/or 600D discussed above with respect to FIGS. 1A-6D.

IC layout diagram generation system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

IC layout diagram generation system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 900.

IC layout diagram generation system 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. IC layout diagram generation system 900 is configured to receive information related to a UI through I/O interface 910. The information is stored in computer-readable medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 10 is a block diagram of IC manufacturing system 1000, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns, e.g., one or more of IC layout diagrams 100-600D discussed above with respect to FIGS. 1A-6D. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (RDF). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes wafer fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, an IC device includes an active area extending in a first direction in a front side of a semiconductor substrate, a first gate electrode overlying the active area and extending in a second direction perpendicular to the first direction, an MD segment extending in the second direction adjacent to the first gate electrode and overlying the active area, and a first FTV directly contacting one of the first gate electrode or the MD segment and extending in a third direction perpendicular to the first and second directions to a back side of the semiconductor substrate. In some embodiments, the IC device includes a first backside power rail extending in the first direction, wherein the first FTV is electrically connected to the first power rail. In some embodiments, the first FTV directly contacts the MD segment, and the IC device includes a second backside power rail extending in the first direction adjacent to the first backside power rail and a backside via extending in the third direction from the active area to the second backside power rail. In some embodiments, the first FTV directly contacts the first gate electrode, and the IC device includes a second gate electrode aligned with the first gate electrode in the second direction and separated from the first gate electrode by a dielectric layer, a second backside power rail extending in the first direction, and a second FTV directly contacting the second gate electrode and extending in the third direction from the second gate electrode to the second backside power rail. In some embodiments, the first FTV directly contacts the MD segment, the IC device includes a second gate electrode extending in the second direction, and the first FTV directly contacts the second gate electrode. In some embodiments, the IC device includes a first signal line positioned in a first backside metal layer, wherein the first FTV directly contacts the MD segment and is electrically connected to the first signal line. In some embodiments, the IC device includes a second signal line positioned in the first backside metal layer or a second backside metal layer and a second FTV directly contacting the first gate electrode and extending in the third direction from the first gate electrode to the second signal line. In some embodiments, the IC device includes a first signal line positioned in a first backside metal layer, wherein the first FTV directly contacts the first gate electrode and is electrically connected to the first signal line.

In some embodiments, a method of manufacturing an IC device includes constructing a plurality of transistors in a front side of a semiconductor substrate, constructing the plurality of transistors including forming an active area extending in a first direction, forming an MD segment overlying the active area and extending in a second direction perpendicular to the first direction, and forming a first gate electrode overlying the active area and extending in the second direction adjacent to the MD segment, and forming a first FTV from a back side of the semiconductor substrate to the first gate electrode or to the MD segment. In some embodiments, the method includes forming a first power rail in the back side of the semiconductor substrate electrically connected to the FTV. In some embodiments, forming the first FTV includes forming the first FTV to the MD segment, forming the first FTV includes forming a backside via from the back side of the semiconductor substrate to the active area, and forming the first power rail includes forming a second power rail in the back side of the semiconductor substrate adjacent to the first backside power rail and electrically connected to the backside via. In some embodiments, forming the first gate electrode includes forming a second gate electrode aligned with the first gate electrode in the second direction and forming a dielectric layer between the first and second gate electrodes, forming the first FTV includes forming the first FTV to the first gate electrode, forming the first FTV includes forming a second FTV from the back side of the semiconductor substrate to the second gate electrode, and forming the first power rail includes forming a second power rail in the back side of the semiconductor substrate electrically connected to the second FTV. In some embodiments, forming the first gate electrode includes forming a second gate electrode in parallel with the first gate electrode and forming the first FTV includes forming the first FTV to the MD segment and to the second gate electrode. In some embodiments, forming the first FTV includes forming the first FTV to the MD segment, and the method includes forming a first signal line in a first backside metal layer and electrically connected to the first FTV. In some embodiments, forming the first FTV includes forming a second FTV from the back side of the semiconductor substrate to the first gate electrode and forming the first signal line includes forming a second signal line in the first backside metal layer or a second backside metal layer and electrically connected to the second FTV. In some embodiments, forming the first FTV includes forming the first FTV to the first gate electrode, and the method includes forming a first signal line in a first backside metal layer and electrically connected to the first FTV.

In some embodiments, a method of generating an IC layout diagram includes arranging a plurality of transistors in an IC cell, the plurality of transistors including an active region, a gate region overlapping the active region, and an MD region overlapping the active region adjacent to the gate region, overlapping the gate region or the MD region with a FTV region, and storing the cell including the FTV region in a cell library. In some embodiments, overlapping the gate region or the MD region with the FTV region includes overlapping one of the gate region or the MD region with a first FTV region, overlapping the gate region or the MD region with the FTV region includes overlapping the other of the gate region or the MD region with a second FTV region, and storing the cell comprising the FTV region in the cell library includes storing the cell comprising each of the first and second FTV regions in the cell library. In some embodiments, the gate region is a first gate region, the plurality of transistors includes a second gate region, and overlapping the gate region or the MD region with the FTV region includes overlapping each of the MD region and the second gate region with the FTV region. In some embodiments, the method includes placing the cell comprising the FTV region in an IC layout diagram, overlapping the FTV region with a metal region in a backside metal layer; and storing the IC layout diagram including the cell in a storage device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
an active area extending in a first direction in a front side of a semiconductor substrate;
a first gate electrode overlying the active area and extending in a second direction perpendicular to the first direction;
a metal-like defined (MD) segment extending in the second direction adjacent to the first gate electrode and overlying the active area; and
a first feed-through via (FTV) directly contacting one of the first gate electrode or the MD segment and extending in a third direction perpendicular to the first and second directions to a back side of the semiconductor substrate.

2. The IC device of claim 1, further comprising:
a first backside power rail extending in the first direction,
wherein the first FTV is electrically connected to the first power rail.

3. The IC device of claim 2, wherein
the first FTV directly contacts the MD segment, and
the IC device further comprises:
a second backside power rail extending in the first direction adjacent to the first backside power rail; and
a backside via extending in the third direction from the active area to the second backside power rail.

4. The IC device of claim 2, wherein
the first FTV directly contacts the first gate electrode, and
the IC device further comprises:
a second gate electrode aligned with the first gate electrode in the second direction and separated from the first gate electrode by a dielectric layer;
a second backside power rail extending in the first direction; and
a second FTV directly contacting the second gate electrode and extending in the third direction from the second gate electrode to the second backside power rail.

5. The IC device of claim 1, wherein
the first FTV directly contacts the MD segment,
the IC device further comprises a second gate electrode extending in the second direction, and
the first FTV directly contacts the second gate electrode.

6. The IC device of claim 1, further comprising:
a first signal line positioned in a first backside metal layer,
wherein the first FTV directly contacts the MD segment and is electrically connected to the first signal line.

7. The IC device of claim 6, further comprising:
a second signal line positioned in the first backside metal layer or a second backside metal layer; and
a second FTV directly contacting the first gate electrode and extending in the third direction from the first gate electrode to the second signal line.

8. The IC device of claim 1, further comprising:
a first signal line positioned in a first backside metal layer,
wherein the first FTV directly contacts the first gate electrode and is electrically connected to the first signal line.

9. A method of manufacturing an integrated circuit (IC) device, the method comprising:
constructing a plurality of transistors in a front side of a semiconductor substrate, the constructing the plurality of transistors comprising:
forming an active area extending in a first direction;
forming a metal-like defined (MD) segment overlying the active area and extending in a second direction perpendicular to the first direction; and
forming a first gate electrode overlying the active area and extending in the second direction adjacent to the MD segment; and
forming a first feed-through via (FTV) from a back side of the semiconductor substrate to the first gate electrode or to the MD segment.

10. The method of claim 9, further comprising:
forming a first power rail in the back side of the semiconductor substrate electrically connected to the FTV.

11. The method of claim 10, wherein
the forming the first FTV comprises forming the first FTV to the MD segment,
the forming the first FTV further comprises forming a backside via from the back side of the semiconductor substrate to the active area, and
the forming the first power rail comprises forming a second power rail in the back side of the semiconductor substrate adjacent to the first backside power rail and electrically connected to the backside via.

12. The method of claim 10, wherein
the forming the first gate electrode comprises:
forming a second gate electrode aligned with the first gate electrode in the second direction; and
forming a dielectric layer between the first and second gate electrodes,
the forming the first FTV comprises forming the first FTV to the first gate electrode,
the forming the first FTV further comprises forming a second FTV from the back side of the semiconductor substrate to the second gate electrode, and
the forming the first power rail comprises forming a second power rail in the back side of the semiconductor substrate electrically connected to the second FTV.

13. The method of claim 9, wherein
the forming the first gate electrode comprises forming a second gate electrode in parallel with the first gate electrode, and
the forming the first FTV comprises forming the first FTV to the MD segment and to the second gate electrode.

14. The method of claim 9, wherein
the forming the first FTV comprises forming the first FTV to the MD segment, and
the method further comprises forming a first signal line in a first backside metal layer and electrically connected to the first FTV.

15. The method of claim 14, wherein
the forming the first FTV further comprises forming a second FTV from the back side of the semiconductor substrate to the first gate electrode, and
the forming the first signal line comprises forming a second signal line in the first backside metal layer or a second backside metal layer and electrically connected to the second FTV.

16. The method of claim 9, wherein
the forming the first FTV comprises forming the first FTV to the first gate electrode, and
the method further comprises forming a first signal line in a first backside metal layer and electrically connected to the first FTV.

17. A method of generating an integrated circuit (IC) layout diagram, the method comprising:
arranging a plurality of transistors in an IC cell, the plurality of transistors comprising:
an active region;
a gate region overlapping the active region; and
a metal-like defined (MD) region overlapping the active region adjacent to the gate region;
overlapping the gate region or the MD region with a feed-through via (FTV) region; and
storing the cell comprising the FTV region in a cell library.

18. The method of claim 17, wherein
the overlapping the gate region or the MD region with the FTV region comprises overlapping one of the gate region or the MD region with a first FTV region,
the overlapping the gate region or the MD region with the FTV region further comprises overlapping the other of the gate region or the MD region with a second FTV region, and
the storing the cell comprising the FTV region in the cell library comprises storing the cell comprising each of the first and second FTV regions in the cell library.

19. The method of claim 17, wherein
the gate region is a first gate region,
the plurality of transistors further comprises a second gate region, and
the overlapping the gate region or the MD region with the FTV region comprises overlapping each of the MD region and the second gate region with the FTV region.

20. The method of claim 17, further comprising:
placing the cell comprising the FTV region in an IC layout diagram;
overlapping the FTV region with a metal region in a backside metal layer; and
storing the IC layout diagram comprising the cell in a storage device.
